(19) United States
(12) Patent Application Publication
(10) Pub. No.: US 2025/0354920 A1
(43) Pub. Date: Nov. 20, 2025

(54) INSPECTION SYSTEM WITH MULTIWAVELENGTH LIGHT SOURCE AND METHOD

(71) Applicant: Taiwan Semiconductor Manufacturing Co., Ltd., Hsinchu (TW)

(72) Inventors: Tai-Yu CHEN, Hsinchu (TW); Hsiao-Lun CHANG, Hsinchu (TW); Shang-Chieh CHIEN, Hsinchu (TW)

(73) Assignee: Taiwan Semiconductor Manufacturing Co., Ltd., Hsinchu (TW)

(21) Appl. No.: 19/286,013

(22) Filed: Jul. 30, 2025

Related U.S. Application Data
(63) Continuation of application No. 18/404,762, filed on Jan. 4, 2024.
(60) Provisional application No. 63/581,067, filed on Sep. 7, 2023.
(60) Provisional application No. 63/614,838, filed on Dec. 26, 2023.

(51) Int. Cl. G01N 21/31; G01N 21/95

(52) U.S. Cl. CPC G01N 21/31; G01N 21/9501; G01N 2201/02

(57) ABSTRACT

A method includes positioning a substrate in an optical path of a multiwavelength light source; generating a first detection result by exposing a first region of the substrate to a first light having a first wavelength band selected by the light source; and generating a second detection result by exposing a second region of the substrate to a second light having a second wavelength band selected by the multiwavelength light source. A system includes a multiwavelength light source including a light source and a wavelength selector in an optical path of light generated by the light source. The system further includes a spectrometer operable to measure a spectrum of a first light selected by the wavelength selector; a mask stage operable to position a mask in the optical path; and a controller operable to adjust a parameter of the multiwavelength light source responsive to the spectrum of the first light.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of a system operable to inspect a substrate according to embodiments of the present disclosure.

FIGS. 2 and 3 are views illustrating systems for inspecting a substrate according to various aspects of the present disclosure.

FIGS. 4A-4E are views of a system for generating a selected single light for inspection and verifying the selection thereof in accordance with various embodiments.

FIG. 5 is a flowchart of a method of performing sensitivity verification in accordance with various embodiments.

FIGS. 6A and 6B are views illustrating a sensitivity verification operation in accordance with various embodiments.

FIGS. 7A-7C are diagrams depicting a calibration substrate in accordance with various embodiments.

FIGS. 8A-9B are views of systems for inspecting a substrate in accordance with various embodiments.

FIG. 10 is a block diagram of a controller in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms such as “about,” “roughly,” “substantially,” and the like may be used herein for ease of description. A person having ordinary skill in the art will be able to understand and derive meanings for such terms.

Semiconductor fabrication generally involves the formation of electronic circuits by performing multiple depositions, etchings, cleanings, annealings and/or implantations of material layers, whereby a stack structure including many semiconductor devices and interconnects between is formed.

Etching is performed in many instances based on a pattern. The pattern may be first transferred to a resist layer by reflecting light from a mask that has the pattern thereon. Defects in the mask are transferred with the pattern, which can result in improper etching and malfunction of the semiconductor devices. As such, inspection of the mask is generally performed prior to using the mask in semiconductor processing. For example, a “golden” digital image of the mask without defects may be captured after the mask is fabricated. Then, prior to using the mask, another digital image may be captured and compared with the golden digital image to determine whether a defect(s) is present. In response to the defect(s) being present, the mask may be cleaned, repaired, reworked or replaced prior to beginning semiconductor processing.

When inspecting a mask, a single wavelength light source directs light toward the mask, which reflects the light back to a detector. However, light of a single wavelength can be insufficient to inspect new generation node masks and support complex mask pattern designs. To satisfy different mask pattern pitches, a tunable wavelength light source function is beneficial for resolution improvement. Another problem is that sensitivity (capture rate) can be non-uniform as inspection frequency increases. Defect signals at different wavelengths have different responses, which can increase risk of missing defects or false detections.

In embodiments of the disclosure, a tunable wavelength light source is implemented. The tunable wavelength light source may include an acousto-optical modulator (AOM) that generates light of multiple wavelengths and a slit for selecting a single wavelength of the multiple wavelengths generated by the AOM. In some embodiments, the tunable wavelength light source has a multiwavelength nonlinear light source instead of the single wavelength light source. In some embodiments, the tunable wavelength light source includes a switchable light source stage instead of the single wavelength light source. The switchable light source stage may include multiple single wavelength light sources instead of the multiwavelength nonlinear light source.

In some embodiments, two spectrometers are included that perform real-time spectrum variation monitoring. Based on feedback from the spectrometers, a laser intensity feedback control loop for inspecting light energy stability may be implemented, and a wavelength feedback control loop with AOM and spectrometer may be implemented to improve wavelength precision in real time. An optical path stabilizer may be included to select light path pointing and/or position control. A local, selected wavelength may be included as an inspection light to overcome resolution or contrast insufficiency.

The embodiments are associated with various benefits. Resolution limitations due to a single wavelength light source can be overcome. Spectrum monitoring is improved due to including the one or more spectrometers in the system. Energy control accuracy is improved by wavelength tuning and calibration due to inclusion of the spectrometer(s). Sensitivity is improved due to defect signal response enhancement by operating at different, selectable wavelengths. A switchable multiwavelength inspection technique can be achieved for output wavelengths ranging from visible light, to ultraviolet (UV), middle ultraviolet (MUV), deep ultraviolet (DUV) and extreme ultraviolet (EUV) domains.

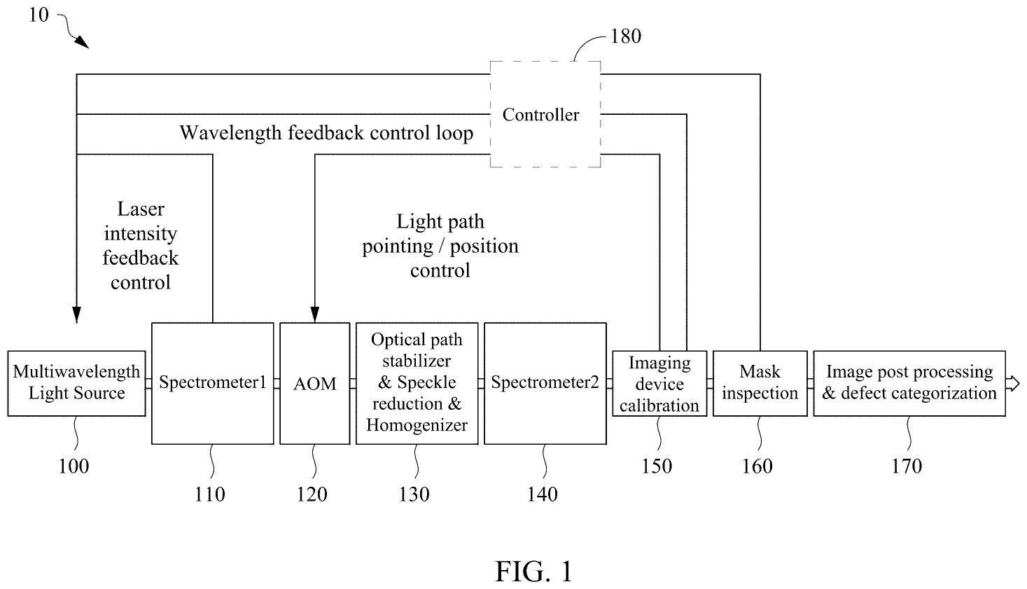

FIG. 1 is a diagram of a system 10 operable to inspect a substrate according to embodiments of the present disclosure.

The system 10 includes a multiwavelength light source 100, one or more spectrometers 110, 140, an acousto-optical modulator (AOM) 120, a multifunctional structure 130, an imaging device calibration apparatus 150, a mask inspection apparatus 160 and an image post-processing and defect categorization apparatus 170. One or more feedback control loops are present between the various components of the system 10 that are beneficial to improving mask inspection quality. Some components may be omitted from view in the system 10 of FIG. 1 for simplicity of illustration. Some components depicted in FIG. 1 may be omitted (e.g., may be optional) in some embodiments.

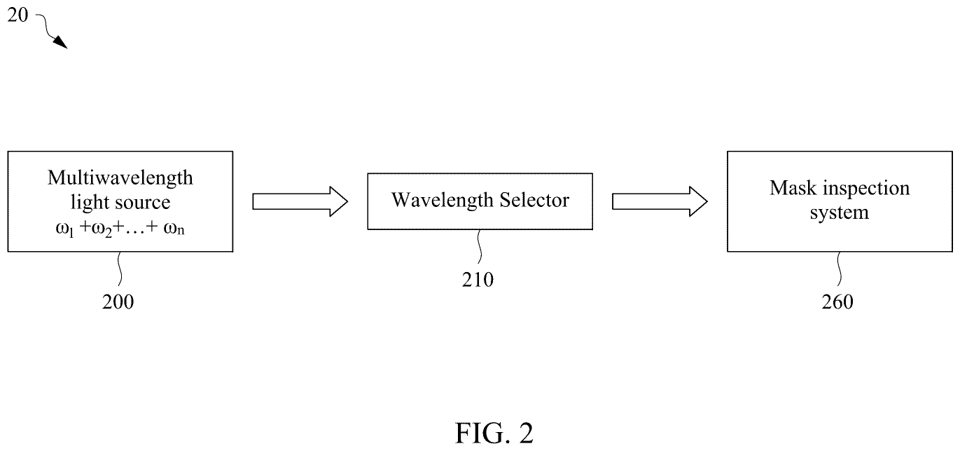

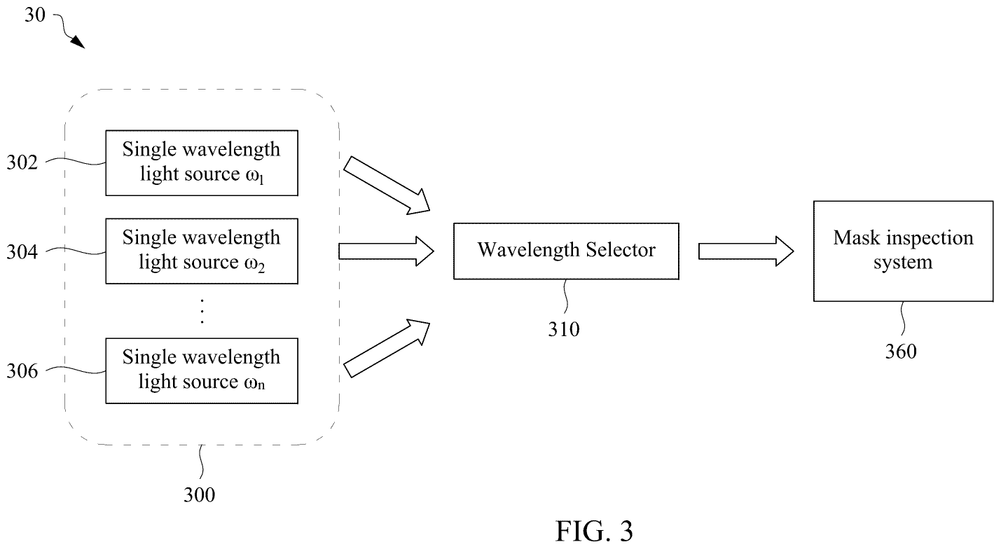

The multiwavelength light source 100 is operable to generate one or more light sources that include different wavelengths. In some embodiments, a tunable multiwavelength inspection light source includes a nonlinear light source system or a switchable light source stage. A nonlinear light source system 20 in accordance with various embodiments is described in greater detail with reference to FIG. 2. A switchable light source stage 30 in accordance with various embodiments is described in greater detail with reference to FIG. 3.

Nonlinear interactions may be generated via various frequency-mixing processes, such as acousto-optics (AO), second-harmonic generation (SHG), third-harmonic generation (THG), high-harmonic generation (HHG), difference-frequency generation (DFG), sum-frequency generation (SFG), optical parametric oscillation (OPO), optical parameter generation (OPG) and the like. A nonlinear light source system may be operable to perform functions of adjusting oscillator cavity length, switching different gain mediums in an oscillator, having nonlinear crystals for harmonic generation such as beta-barium borate (BBO), lithium triborate (LBO), cesium lithium borate (CLBO), bismuth borate (BiBO), potassium titanyl phosphate (KPT) and the like.

In some embodiments, the multiwavelength light source 100 includes an inspection light source including one or more laser sources. The laser source(s) have laser wavelength that can be a single wavelength or include multiple wavelengths, and can include one or more of a fundamental laser or a harmonic generator.

Output of the multiwavelength light source 100 may be received by a first spectrometer 110. Spectrometry is included to monitor a wavelength modulating result to determine whether the target laser wavelength is at a selected wavelength or not. For example, the first spectrometer 110 may detect abnormal laser amplification and/or prevent against false wavelengths. The first spectrometer 110 can include one or more of a grating, a slit and preamplifier, an imaging device (e.g., CMOS, CCD or TDI) and/or a photodiode. The first spectrometer 110 can analyze spectrum distribution and intensity of the light outputted by the multiwavelength light source 100, which can be used in a laser intensity control loop to select light intensity. In the inspection system 10, to improve accuracy of a modulating result, two spectrometer devices may be installed in two positions, as depicted in FIG. 1. The first spectrometer 110 is positioned at an outlet position of the multiwavelength light source 100 (e.g., a nonlinear laser system) to determine whether an incoming light wavelength distribution is within a selected spectrum for measurement.

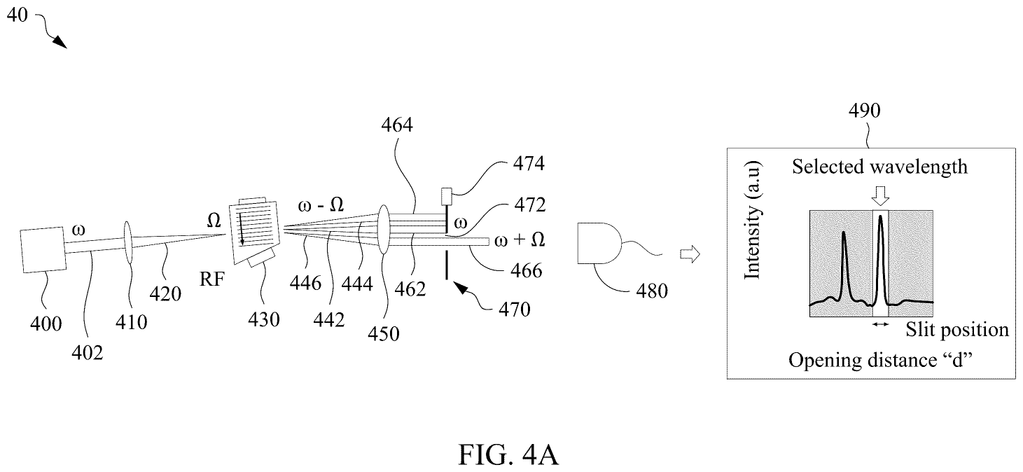

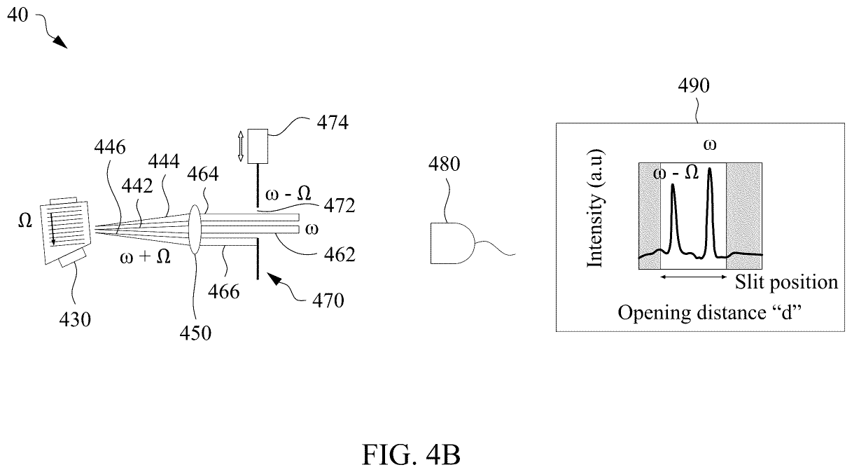

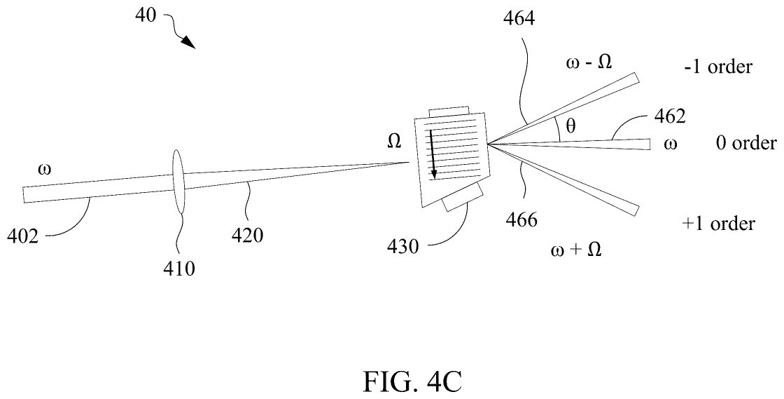

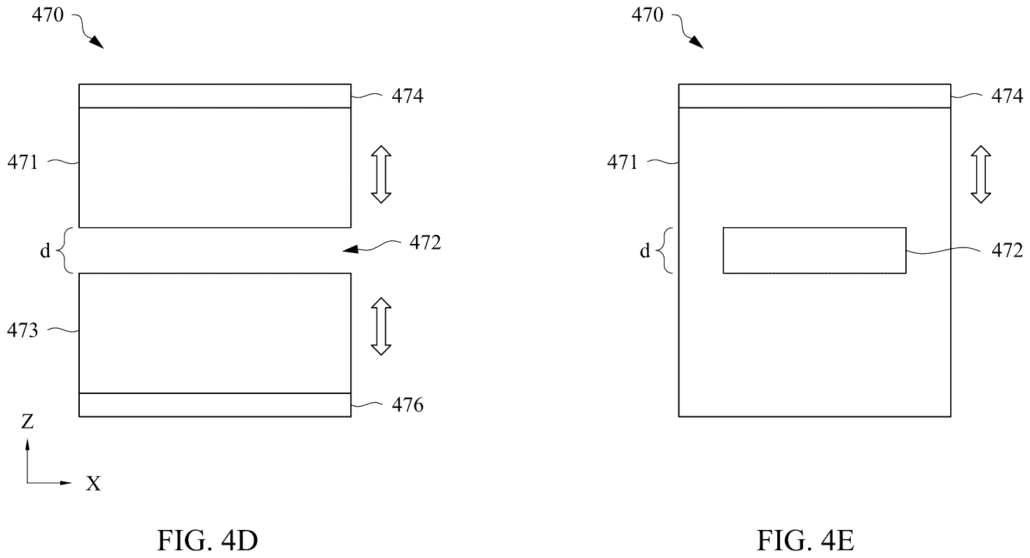

A second spectrometer 140 may be placed below the mask stage to capture on target (mask) wavelength distribution in the selected spectrum for measurement. The second spectrometer 140 may be similar in most respects to the first spectrometer 110, but may be positioned following the multifunctional structure or apparatus 130. Inclusion of the two spectrometry devices 110, 140 is beneficial for the AOM 120 to improve tuning to a selected wavelength based on known (e.g., historical or stored) background information and effectively reduce light noise by a moving slit. A moving slit 470 in accordance with various embodiments is described in greater detail with reference to FIGS. 4A-4C.

The acousto-optical modulator (AOM) 120 may perform acousto-optical modulation, which is depicted in greater detail in FIGS. 4A-4C. To achieve a multiwavelength light source, an AOM is a device that is operable to modulate an original wavelength to a new wavelength within a range. The AOM 120 may include a frequency modulator, such that a tunable laser wavelength may be generated via RF signal modulation. Stability of the RF signal may be monitored by the AOM 120 or an external monitoring device.

Embodiments of the disclosure include an AOM, spectrometer(s) and one or more control loop(s). The acousto-optical modulation may be performed by the AOM 120 that operates based on an acoustic optical effect to provide diffraction and shift frequency for incoming light. A periodic RF signal may be input to a piezoelectric transducer of the AOM 120, whereby an acoustic wave influences expansion and compression of a change of refractive index. Interaction of phonons and photons can achieve sum frequency generation (SFG) or difference frequency generation (DFG) based on momentum conservation and energy conservation in the nonlinear system. Adopting the AOM 120 to modulate wavelength improves simplicity of the system. For example, the AOM 120 can be retrofitted into existing systems easily as an in-situ component and thereby immediately provide selection of wavelengths of light for mask inspection that are beneficial for different mask pattern dimensions (e.g., pitch and spacing) and that improve defect signal detection.

The multifunctional structure or apparatus 130 may include one or more of an optical path stabilizer, speckle reducer and homogenizer. In some embodiments, the multifunctional apparatus 130 includes one or more of a diffuser(s), homogenizer(s), waveplate(s), lens(es) and mirror(s) for light quality improvement. The multifunctional apparatus 130 may be operable to perform optical path pointing and/or position correction for the AOM 120.

The optical path stabilizer (OPS) can be a system that improves stability and consistency of optical path length in an optical system, which is beneficial in high-resolution systems, such as those used for EUV mask inspection. The optical path stabilizer can compensate for environmental factors or equipment-induced vibrations that might cause changes or disturbances in the optical path, which is beneficial to providing a consistent and high-quality output. OPSs can use a variety of techniques to stabilize the optical path, such as moving mirrors or lenses, or using acousto-optic devices.

Speckles can refer to granular interference patterns that occur when coherent light, like a laser, reflects off or passes through a rough surface. In the system 10, speckles can introduce noise or false indications, increasing difficulty in correctly analyzing the semiconductor mask. Speckle reduction techniques can include software algorithms, introducing controlled randomness to an optical setup or using multiple wavelengths or angles of illumination. In some embodiments, the techniques to reduce speckle noise include spatial filtering, temporal filtering, polarization filtering and the like.

A homogenizer can be used to improve intensity distribution uniformity of the light source across its profile, which is beneficial for inspections because non-uniform illumination can introduce artifacts or shadows that can lead to incorrect analysis. Homogenizers can be made of or include a series of lenses, prisms, or other optical elements that distribute the light evenly. Homogenizers can use a variety of techniques to create a uniform light distribution, such as diffusion, scattering, and diffraction. In the context of EUV mask inspection systems, a homogenizer can improve uniform illumination of the mask, making it easier to identify defects or irregularities.

The second spectrometer 140 follows the multifunctional apparatus 130 and may be operable to feedback spectrum information to the AOM 120, feedback laser power information to the multiwavelength light source 100, detect abnormal wavelengths, and the like.

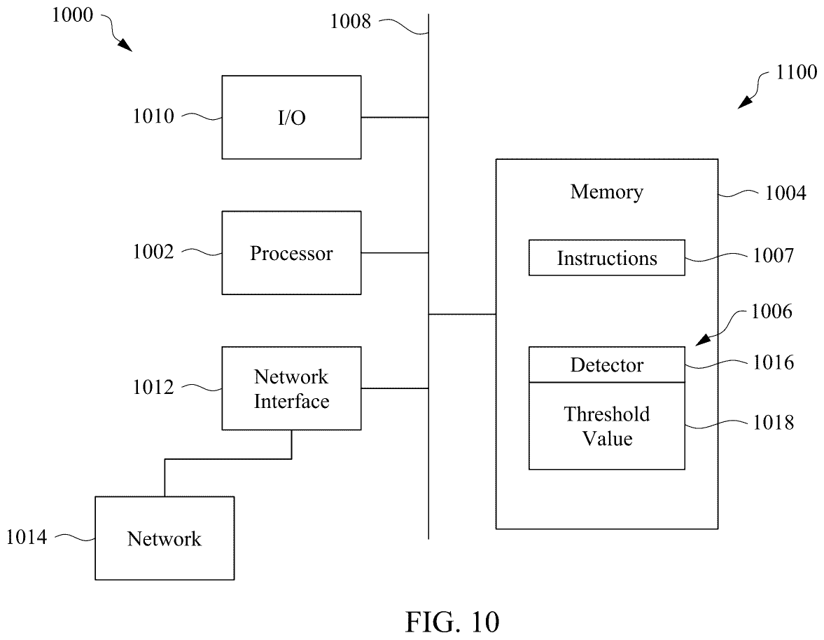

The imaging device calibration apparatus 150 is operable to calibrate or select parameters of an imaging device, which may include a charge-coupled device (CCD) imaging device or complementary metal-oxide semiconductor (CMOS) imaging device. The CCD imaging device and the CMOS imaging device may each be a time delay integration (TDI) imaging device. In some embodiments, the imaging device calibration apparatus 150 includes a controller (e.g., a microcontroller unit or “MCU”), processor, multiprocessor, or the like. The imaging device calibration apparatus 150 may be in data communication with an optical sensor for selecting parameters thereof. In some embodiments, the system 10 includes a controller 180 and the imaging device calibration apparatus 150 is included in the controller 180. A controller 1000 in accordance with various embodiments is described in greater detail with reference to FIG. 10.

Various parameters of CCD, CMOS, TDI CCD, and TDI CMOS sensors may be controlled in real-time via, for example, an MCU, such as the controller 180. Gain of the sensor can control how much the signal from each pixel is amplified. Increasing the gain can improve the sensitivity of the sensor but can also increase noise. The offset of the sensor controls the black level of the image. Increasing the offset can reduce the noise in the image but can also make it more difficult to detect small defects in the mask. The integration time can refer to the amount of time that the sensor is exposed to light. Increasing the integration time can improve signal-to-noise ratio (SNR) of the image but can also make the sensor more susceptible to motion blur. The sensor can be triggered to start and stop integration in real-time, which can be beneficial to synchronize the sensor with the mask scanner or other devices in the inspection system.

In addition to these parameters, some sensors may also allow for real-time control of other features, such as the number of TDI stages or the shift frequency. The parameters that can be controlled or selected in real-time can vary depending on the sensor and the MCU.

Following are examples of how real-time control or selection of sensor parameters can be used in semiconductor mask inspection. The gain of the sensor can be adjusted to compensate for changes in lighting conditions. The offset of the sensor can be adjusted to compensate for changes in the background noise level. The integration time of the sensor can be adjusted to improve the SNR for different mask features. The sensor can be triggered to start and stop integration at selected points in the mask scanning process, which can be beneficial to synchronize the sensor with the mask scanner or to capture images of selected regions on the mask.

The CCD, CMOS, TDI CCD, and/or TDI CMOS sensors may include various characteristics that are beneficial to semiconductor mask inspection. For example, a CCD sensor may have characteristics, such as pixel size, well depth and readout noise. A smaller size of each pixel on the sensor may be beneficial for higher resolution images but can also result in more noise. Well depth can refer to a maximum number of photoelectrons that a pixel can hold before it saturates, which can be beneficial for low-light imaging and imaging high-contrast scenes. Readout noise can refer to amount of noise that is introduced into an image during a readout process. Reducing readout noise may be beneficial for low-light imaging and for imaging scenes with high dynamic range.

For a CMOS sensor, pixel size, fill factor and dark current may be characteristics that are beneficial to semiconductor mask inspection. As described previously, smaller pixels may allow for higher resolution images but can also result in more noise. Fill factor can refer to percentage of the pixel area that is sensitive to light. A higher fill factor can result in a higher sensitivity sensor. Dark current can refer to an amount of current that flows through the CMOS sensor even when it is not exposed to light. Dark current reduction can be beneficial for low-light imaging and for imaging scenes with high dynamic range.

In a TDI CCD sensor, characteristics that can be beneficial may include number of stages and shift frequency. The number of stages is associated with number of times that image charge packets are shifted along rows of the CCD sensor. A higher number of stages can result in a higher signal-to-noise ratio (SNR) image. Shift frequency can refer to frequency at which the image charge packets are shifted along the rows of the CCD sensor. Matching the shift frequency to speed of the object being imaged (e.g., the mask) is beneficial to improve imaging quality.

In a TDI CMOS sensor, number of stages, shift frequency and rolling shutter may be characteristics that are beneficial in one or more ways to mask inspection. CMOS sensors can use a rolling shutter, which refers to the sensor being read out one row at a time. The rolling shutter can result in image distortion when the object being imaged (e.g., the mask) is moving. TDI CMOS sensors can include a global shutter, which reads out the entire sensor at once. This can be beneficial to reduce or eliminate image distortion but may increase cost and/or complexity of the CMOS sensor.

In the context of semiconductor mask inspection, the following characteristics may be particularly beneficial: pixel size, well depth, readout noise, number of TDI stages, shift frequency, rolling shutter and integration time. The pixel size can be selected to be small enough to resolve the features on the mask. The well depth can be selected to be high enough to avoid saturating the pixels when imaging bright features on the mask. The readout noise can be selected to be low enough to avoid obscuring small defects on the mask. The number of stages can be selected to be high enough to achieve the selected SNR. The shift frequency can be selected to be matched to the speed of the mask scanner. A global shutter may be selected to avoid image distortion. Semiconductor mask inspection can be performed in low-light conditions, such that sensors with long integration times may be beneficially selected.

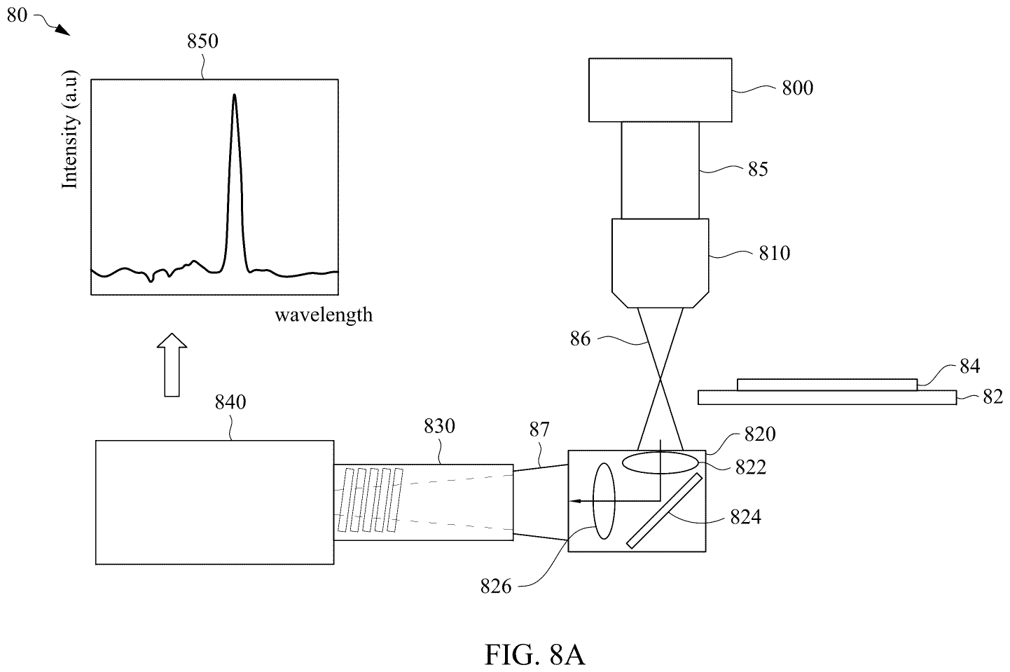

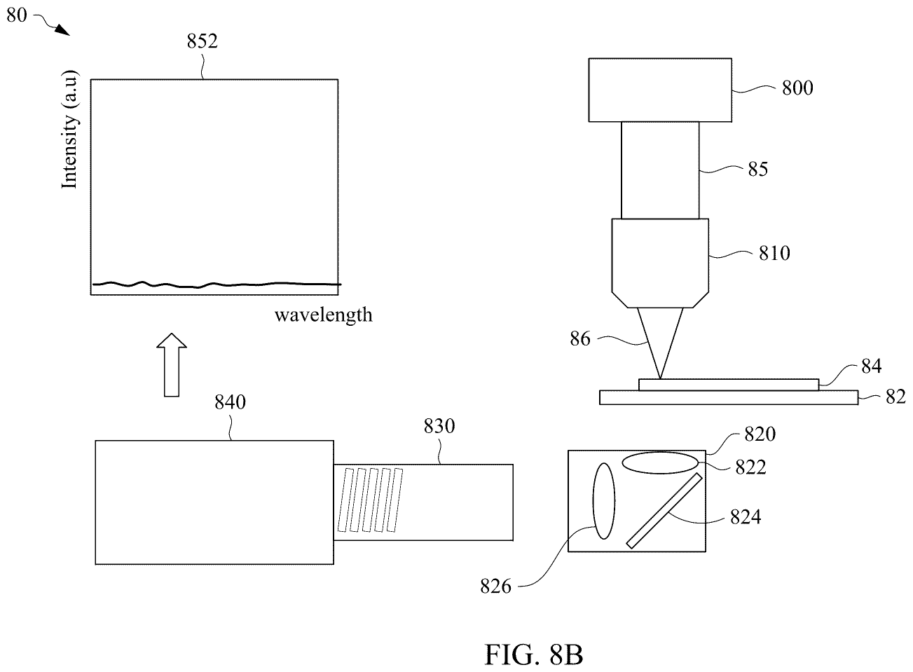

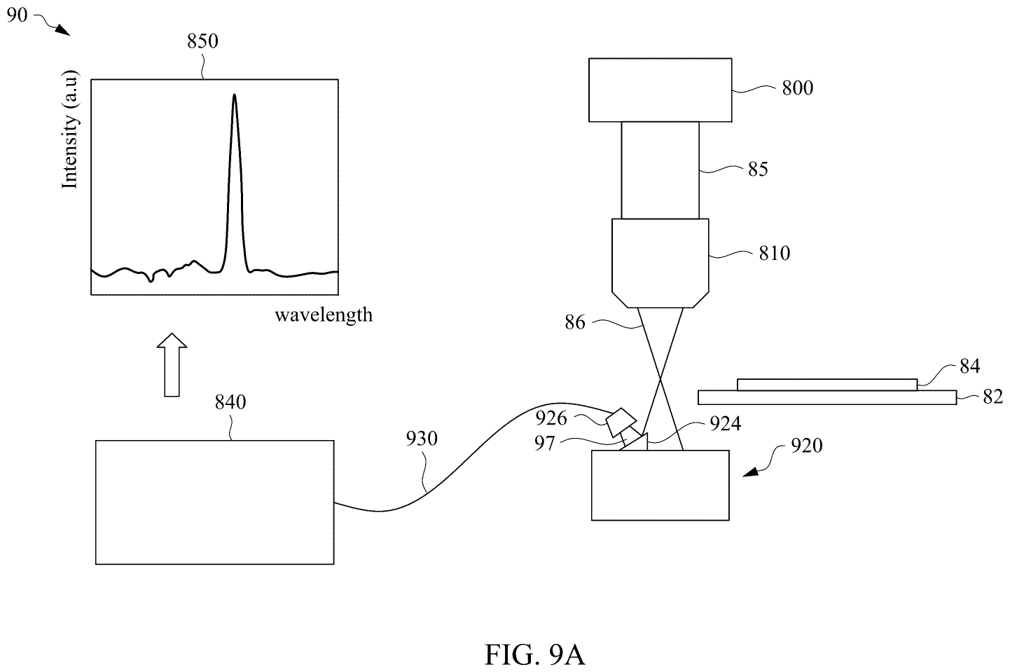

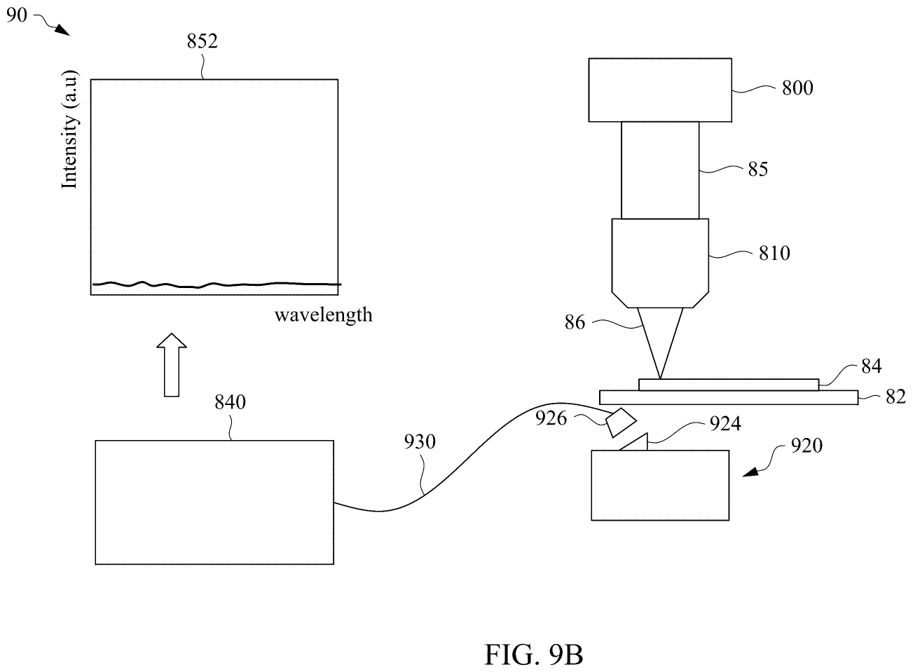

The mask inspection system 160 may include one or more components of the system 10, such as the multiwavelength light source 100, the AOM 120, the multifunctional apparatus 130 and the controller that selects parameters of the one or more components. The mask inspection system 160 may include additional components other than those illustrated in FIG. 1. For example, the mask inspection system 160 may include an imaging device or system. The imaging system can capture images of the mask via a sensor thereof, which may be a CCD sensor or CMOS sensor. The mask inspection system 160 may include a reflective imaging system, in which the EUV light is reflected from the mask and onto the sensor. The mask inspection system 160 may include a stage that is operable to move the mask relative to the illumination and imaging systems. This allows the entire mask to be inspected. The mask inspection system 160 may include an image processing system, which is operable for analyzing the images of the mask and detecting defects. This may be performed via a variety of image processing algorithms. Mask inspection systems 80, 90 in accordance with various embodiments are described in greater detail with reference to FIGS. 8A-9B.

The operating principle of the mask inspection system 160 can include placing the mask on the stage and illuminating the mask with light from the multiwavelength light source 100. The reflected light is then captured by the imaging system and analyzed by the image processing system. The image processing system detects any defects in the mask and can optionally generate a report that is used by an operator to determine whether the mask is acceptable. In addition to the above, the mask inspection system 160 may include a contamination control system that has a variety of contamination control devices or apparatuses, such as a HEPA filter. The mask inspection system 160 may include a temperature control system, which is operable to maintain the mask at a substantially constant temperature during inspection. This is because changes in temperature can cause the mask to expand or contract, which can lead to defects in the images. The mask inspection system 160 may include a vibration control system, which can include a vibration isolation table that is beneficial to reduce vibration.

The image post-processing and defect categorization apparatus 170, or simply “the processing apparatus 170,” is operable to process the images of the mask captured by the mask inspection system 160 and determine a type and/or number and/or location of defect(s) in the mask based on the processed images. In some embodiments, the processing apparatus 170 is included in the mask inspection system 160. In some embodiments, the processing apparatus 170 is included in the controller described previously, or is another controller separate from the controller described previously.

A variety of image processing algorithms can be used to detect defects by the processing apparatus 170, which may include one or more of thresholding, edge detection, template matching, machine learning and the like. Thresholding can include converting an image to a binary image, where each pixel is either black or white. The pixels are then determined to be defective or non-defective based on their intensity. Edge detection algorithms can be used to detect the edges of objects in an image. Defects in masks can cause changes in the edges of objects. By detecting these changes, edge detection algorithms can be used to identify defects. Template matching algorithms can be used to detect defects by comparing the image to a reference image of a defect-free mask. Any differences between the two images are identified as defects. Machine learning algorithms can be trained to detect defects in masks. These algorithms may be trained on a dataset of images of defective and non-defective masks. Once trained, the algorithm can be used to identify defects in new images.

The selected image processing algorithm(s) used in a mask inspection system can depend on type of defects that are being inspected. For example, a mask inspection system for EUV masks may use different algorithms than a mask inspection system for other types of masks. Types of defects in masks can include one or more of pinhole defects, bridge defects, particle defects and the like. Pinhole defects are small holes in the mask, which can be detected using thresholding or template matching algorithms. Bridge defects are small bridges of material that connect two features on the mask and can be detected using edge detection or machine learning algorithms. Particle defects are small particles that are deposited on the mask that can be detected using thresholding or machine learning algorithms. In some embodiments, template matching may be used for any of the defects just described.

FIGS. 2 and 3 are views illustrating systems for inspecting a substrate according to various aspects of the present disclosure.

In FIG. 2, a system 20 may include a multiwavelength light source 200 that generates a single light having multiple wavelengths, which may be represented as ω₁+ω₂+ . . . +ωₙ, where “n” is an integer exceeding 1. The multiwavelength light source 200 may be a tunable multiwavelength inspection light source that includes a nonlinear light source. The nonlinear light source may generate single-wavelength lights, and one or more lenses may positioned to cause paths of the single-wavelength lights to travel in parallel and be incident on the wavelength selector 210.

Nonlinear interaction can be generated via one or more frequency-mixing processes such as acousto-optics (AO), second-harmonic generation (SHG), third-harmonic generation (THG), high-harmonic generation (HHG), difference-frequency generation (DFG), sum-frequency generation (SFG), optical parametric oscillation (OPO), optical parameter generation (OPG) and the like. The multiwavelength light source 200 may be operable to adjust oscillator cavity length, switch different gain mediums in an oscillator and/or use nonlinear crystals for harmonic generation such as BBO, LBO, CLBO, BIBO, KPT and the like. In some embodiments, the multiwavelength light source 200 includes a single laser, a first lens, an AOM and a second lens that are operable to generate three or more single-wavelength lights. A multiwavelength light source including an AOM is described in greater detail with reference to FIGS. 4A-4C.

In some embodiments, nonlinear crystals are used in the multiwavelength light source to generate light at multiple wavelengths via a process referred to as nonlinear optical frequency conversion. Nonlinear optical frequency conversion is a process of converting light from a single wavelength to another by interacting the light with a nonlinear crystal. The wavelength conversion that occurs can be selected based on a type of nonlinear crystal included and properties of the incident light. For example, a nonlinear crystal may be used to generate a multiwavelength light source via optical parametric oscillation (OPO). OPO is a nonlinear optical process that generates two output beams of light, which may be referred to as a signal beam and an idler beam, from a single input beam. The wavelengths of the signal and idler beams are selected by properties of the nonlinear crystal and wavelength of the input beam. One example of an OPO multiwavelength light source is a YAG:OPO laser. The YAG:OPO laser is a type of OPO laser that includes a yttrium aluminum garnet (YAG) crystal as the nonlinear crystal. YAG:OPO lasers can generate light at a wide range of wavelengths from ultraviolet to infrared.

Another way to use a nonlinear crystal to generate a multiwavelength light source is via a process called supercontinuum generation. Supercontinuum generation is a nonlinear optical process that generates a broad spectrum of light from a single input beam. A spectrum of light that is generated can be selected based on properties of the nonlinear crystal and the input beam parameters. An example of a supercontinuum generation multiwavelength light source is a titanium-sapphire laser. The titanium-sapphire laser is a type of supercontinuum laser that uses a titanium-sapphire crystal as the nonlinear crystal. Titanium-sapphire lasers can generate a very broad spectrum of light, from ultraviolet to infrared.

In some embodiments, the multiwavelength light source 200 is or includes a white light source that includes one or more nonlinear crystals. The white light source can include a nonlinear crystal that frequency doubles a laser beam. For example, a white light source can be generated by frequency doubling a green laser beam using a potassium dihydrogen phosphate (KDP) crystal.

The system 20 includes a wavelength selector 210 that receives the single light from the multiwavelength light source 200. The wavelength selector 210 is operable to select one of the multiple lights, each of which carries a single wavelength or a narrow band of wavelengths centered on a single wavelength. A wavelength selector 470 in accordance with various embodiments is described in greater detail with reference to FIGS. 4A-4C. Briefly, the wavelength selector 210 may include a movable slit that is arranged after the second lens of the multiwavelength light source 200 to select one of the multiple lights as a light source for inspection.

The system 20 includes a mask inspection system 260 that receives the selected light from the wavelength selector 210. The mask inspection system 260 may be similar in most respects to the mask inspection system 160 described with reference to FIG. 1. Briefly, the mask inspection system 260 positions a mask in a path of the selected light, such that a reflection of the mask is generated by the selected light. Images of the reflection are captured by an imaging sensor, and the images can be processed to determine presence or absence of defects in the mask, as described with reference to FIG. 1.

In FIG. 3, a system 30 includes a light source 300 that includes a plurality of single-wavelength light sources 302, 304, . . . , 306. Three single-wavelength light sources 302, 304, 306 are illustrated in FIG. 3. The light source 300 may include fewer or additional light sources than the three single-wavelength light sources 302, 304, 306 depicted in FIG. 3. Each of the single-wavelength light sources 302, 304, 306 may generate a single light that is of a selected wavelength or a selected narrow band of wavelengths centered around the selected wavelength. For example, a first single-wavelength light source 302 may generate single light that is of a first wavelength ω₁, a second single-wavelength light source 304 may generate single light that is of a second wavelength ω₂ and an nth single-wavelength light source 306 may generate single light that is of an nth wavelength ωₙ, “n” being an integer that exceeds 1.

The system 30 includes a wavelength selector 310 that may be similar in most respects to the wavelength selector 210 described with reference to FIG. 2. The wavelength selector 310 is operable to select one of the single lights generated by the light source 300 to be incident on the mask that is under inspection.

FIGS. 4A-4E are views of a system 40 for generating a selected single light for inspection and verifying the selection thereof in accordance with various embodiments. The system 40 can be referred to as an AOM-based multiwavelength light source 40.

In FIG. 4A, the system 40 includes a light source 400, a first lens 410, an AOM 430, a second lens 450 and a wavelength selector 470. FIG. 4A also depicts a spectrometer 480 that can verify wavelength of light selected by the wavelength selector 470.

The light source 400 may be operable to generate light 402 of a single wavelength ω, such as a laser, and may be a laser light source 400. Output wavelength range of the light source 400 may be in a wavelength domain, such as a visible light domain, a UV domain, an MUV domain, a DUV domain, an EUV domain or the like. The light source 400 may include a visible domain laser, such as a helium-neon laser, an argon laser, a krypton laser, or the like. In some embodiments, the light source 400 includes an excimer laser, a helium-cadmium laser, a nitrogen laser, an argon fluoride laser, a krypton fluoride laser, a free-electron laser or the like.

In a microscopic inspection system, diffraction is associated with wavelength of incoming light. The relation of wavelength and resolution can be indicated as RESOLUTION∝λ/NA, where “NA” refers to numerical aperture. For a microscopic inspection system in operation, basic resolution improves due to contrast enhancement, which allows resolution to exceed simple optical design. When wavelength is changed, the resolution is changed accordingly. This means that a signal response of a defect also changes accordingly. When wavelength is decreased, resolution is enhanced. As such, defect sensitivity verification may be performed. The sensitivity verification can include line space patterns, hole patterns, inclined line patterns, brightness/darkness patterns and other complex patterns.

In confined modulating wavelength regions (e.g., around a few nanometers), chromatic optics tolerance (e.g., central wavelength ±10%) can be compensated for except for some optical elements. However, these potential disadvantages can be solved at a system level, for example, by an in-line optics switch. Optics-related calibration can include focal length, astigmatism, flare, polarization, alignment and the like. A lens mounted with an actuator and combined with an optical path and beam size correction system can increase position accuracy and provide appropriate divergence or convergence angles in use. The imaging device (e.g., a CCD or CMOS sensor) can also perform calibration, such as shading calibration and gain calibration.

The first lens 410 may be operable to direct and/or focus the light 402 onto the AOM 430. Light exiting the first lens 410 may refer to as directed light 420. The first lens 410 may be or include an aspheric lens, which may be made from fused silica or other materials that reduce aberrations and increase throughput efficiency. Fused silica may be used due to its low thermal expansion coefficient and high resistance to laser-induced damage. Aspheric lenses may be beneficial for correcting for spherical aberration, providing a more focused point, which can be advantageous in mask inspection where defects can be very small. High numerical aperture (NA) lenses may be used to increase resolution. The first lens 410 may include one or more coatings applied thereto to reduce reflections and improve transmission at the selected laser wavelength being used. In some embodiments, the coatings include an anti-reflective coating. In some embodiments, the first lens 410 includes a collimating lens. The system 40 may further include optional polarizers or additional optical elements before or after the first lens 410.

The system 40 includes an AOM 430. The AOM 430 may include an acousto-optical material, which may be a transparent crystal such as tellurium dioxide (TeO₂) or quartz, selected based on acousto-optic properties such as efficiency and transparency at selected wavelengths. The AOM 430 may include an ultrasonic transducer that is attached to the acousto-optical material and generates sound waves when an electrical signal is applied thereto. The ultrasonic transducer may be a piezoelectric transducer in some embodiments. The AOM 430 may include a radio frequency (RF) driver that generates a radio frequency signal that drives the ultrasonic transducer. Frequency and amplitude of the RF signal can control characteristics of a sound wave and, consequently, modulation of the light 420.

In operation, the RF driver can send an electrical signal to the ultrasonic transducer, which then produces sound waves that propagate through the acousto-optical material or “crystal.” As the sound wave travels through the crystal, the sound wave can induce a periodic change in refractive index of the acousto-optical material, thereby forming a dynamic diffraction grating. A collimated light beam 420 (e.g., from the laser 400) is directed into the crystal where it encounters the dynamic diffraction grating. Depending on properties of the sound wave (e.g., frequency and amplitude), the incident light beam is diffracted. A first-order diffracted beam can be used for modulation, although higher-order beams can also be utilized in some embodiments. By selecting the frequency and amplitude of the RF signal, angle and intensity of the diffracted light can be selected, thereby achieving modulation in real-time. This is described in greater detail with reference to FIG. 4C.

In FIG. 4A, the AOM 430 outputs three lights 442, 444, 446 that have different wavelengths. A first light 442 has a same wavelength ω as that of the light 420 incident on the AOM 430. A second light 444 has a second wavelength ω−Ω. A third light 446 has a third wavelength ω+Ω. In the preceding description, “Ω” refers to RF frequency of the electrical signal applied by the RF driver. The second wavelength ω−Ω can be referred to as a −1^{st} order wavelength, and the third wavelength ω+Ω can be referred to as a +1^{st} order wavelength.

The system 40 includes a second lens 450 through which the three lights 442, 444, 446 pass prior to reaching the wavelength selector 470. The second lens 450 may be similar in many respects to the first lens 410. The second lens 450 may be a collimator lens that is operable to make beams having angular offset parallel. Namely, after passing through the second lens 450, the three lights 442, 444, 446 that had angular offset become parallel lights 462, 464, 466, respectively that are parallel to each other. The parallel lights 462, 464, 466 exiting the second lens 450 are incident on the wavelength selector 470.

The system 40 includes the wavelength selector 470. The wavelength selector 470 includes a moving slit 472 that is controlled by a motion controller 474. Insertion of the moving slit 472 following the AOM 430 allows the slit 472 to operate as a color filter to select a wavelength that is beneficial for inspection. Opening distance “d” or size of the moving slit 472 may be associated with wavelength accuracy. Motion of the moving slit 472 may be driven by a high-precision control motor or piezoelectric transducer (PZT) 474, which can select “d” width and position of the slit. When “d” is smaller, a more highly purified wavelength can be selected and energy output is reduced. When “d” is increased, greater energy output is achieved while more wavelengths outside a selected band may be included in the output light used for inspection. In the example depicted in FIG. 4A, the third light 466 is selected by the wavelength selector 470 while the first and second lights 462, 464 are blocked by the wavelength selector 470. Wavelength selectors in accordance with various embodiments are described in greater detail with reference to FIGS. 4D and 4E.

A spectrometer or spectrometry system 480 is optionally and/or selectably positioned in an optical path of the parallel lights 462, 464, 466. The spectrometer 480 may be an embodiment of the second spectrometer 140 described with reference to FIG. 1. In the example of FIG. 4A, the spectrometer 480 in operation detects amplitude and wavelength of the third light 466 that passes through the moving slit 472. The spectrometer 480 may generate digital data that represents the amplitude and wavelengths of light detected by the spectrometer 480. One representation of the digital data is a graph 490 depicted in FIG. 4A. In some embodiments, the digital data is in another data format, such as an array, table or other appropriate data format. The digital data may be stored in memory in a controller, a database and/or local memory of the spectrometer 480.

A control loop can link spectrometry 480, the AOM 430 and the moving slit 472. When output spectrometry is out of range or abnormal, the control loop can trigger wavelength calibration to adjust one or more of position and/or opening size of the moving slit 472, RF frequency and amplitude of the AOM 430 (e.g., RF power can be controlled to below a saturation level) and energy stability.

In FIG. 4B, in some instances, when the opening distance “d” is so large that high-amplitude signals at other wavelengths outside the selected band pass into a spectrometer 480, the system 40 can force stop based on operating status being wrong or in error. In the example depicted in FIG. 4B, the moving slit 472 is positioned such that the first and second lights 462, 464 pass through while the third light 466 is blocked. The opening size of the moving slit 472 is larger than depicted in FIG. 4A, which allows two lights 462, 464 to pass through instead of only one. As such, the spectrometer 480 detects multiple amplitude peaks at narrow bands around the wavelengths of the first and second lights 462, 464. In response to more than one peak being detected, the spectrometer 480 or a controller in data communication therewith can trigger a force stop of the system 40.

FIG. 4C depicts operation of the AOM 430. In some embodiments, operation of the AOM 430 may be such that output separation angle θ between a zeroth order wavelength and a first order wavelength is expressed as θ=λ*Ω/V, where Ω refers to RF frequency of the RF driver, λ refers to laser wavelength of the light 420 and V refers to acoustic velocity. Then, frequency of the output laser 462, 464, 466 is in a range of ω+/−Ω, where ω refers to frequency of the input laser 402. In some embodiments, such as for an EUV or optical mask inspection tool, the RF frequency may be in a range of sub-GHz to multiple GHz for the AOM 430, corresponding to an operating range of about sub-nanometer to multiple nanometers.

FIGS. 4D and 4E are views illustrating the wavelength selector 470 in accordance with various embodiments.

In FIG. 4D, the wavelength selector 470 includes two plates 471, 473 that are separated by an opening 472 having dimension “d” in the vertical direction Z. One or more actuators 474, 476 may be connected to the respective plates 471, 473 to control motion of the plates 471, 473 along the vertical direction Z. Namely, the plates 471, 473 may be operable to move independently of one another under control of the actuators 474, 476, which may be high-precision control motors or piezoelectric transducers (PZTs) as described previously with reference to FIG. 4A. In some embodiments, the actuators 474, 476 are substantially the same or of the same type (e.g., both are PZTs). In some embodiments, the actuators 474, 476 are different from each other. For example, the actuator 476 may be a lower-precision control motor while the actuator 474 may be a PZT, or another suitable combination of actuators 474, 476. In the wavelength selector 470 of FIG. 4D, the dimension “d” of the opening 472 and the position of the opening 472 along the Z-axis direction may both be controlled, which may be beneficial to select a single wavelength of light with high precision to obtain increased signal energy while rejecting other wavelengths of light.

In FIG. 4E, the wavelength selector 470 includes a single plate 471 having an opening 472 therein instead of the two plates 471, 473. The opening 472 may be fully embedded within the single plate 471, such that the dimension “d” of the opening 472 in the vertical direction Z is fixed or constant. In such embodiments, a single actuator 474 may be included that controls position of the opening 472 without controlling the dimension “d” of the opening 472. Control of the wavelength selector 470 depicted in FIG. 4E may be simpler than that described with reference to FIG. 4D. However, the wavelength selector 470 of FIG. 4D may provide somewhat better signal energy performance due to having a variable dimension “d” instead of the fixed dimension “d” of FIG. 4E.

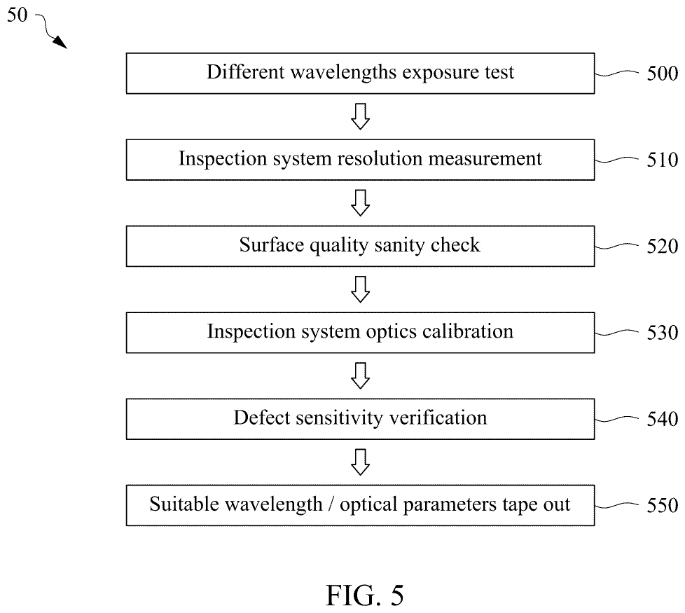

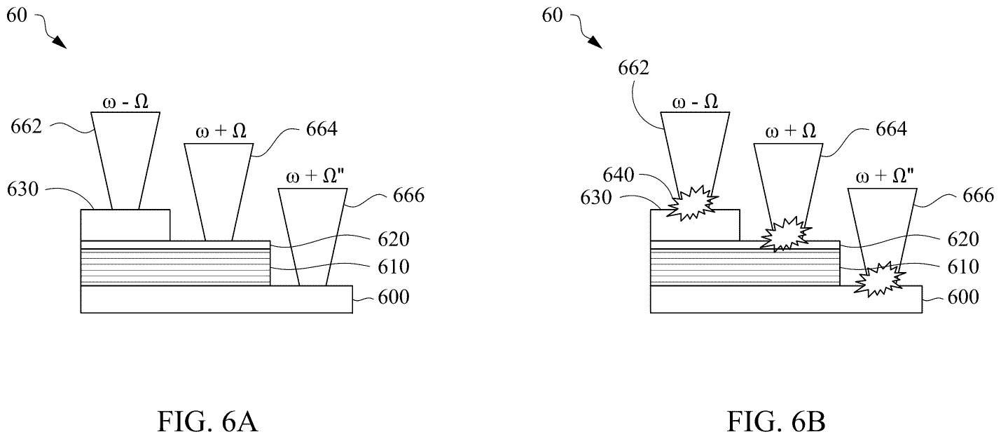

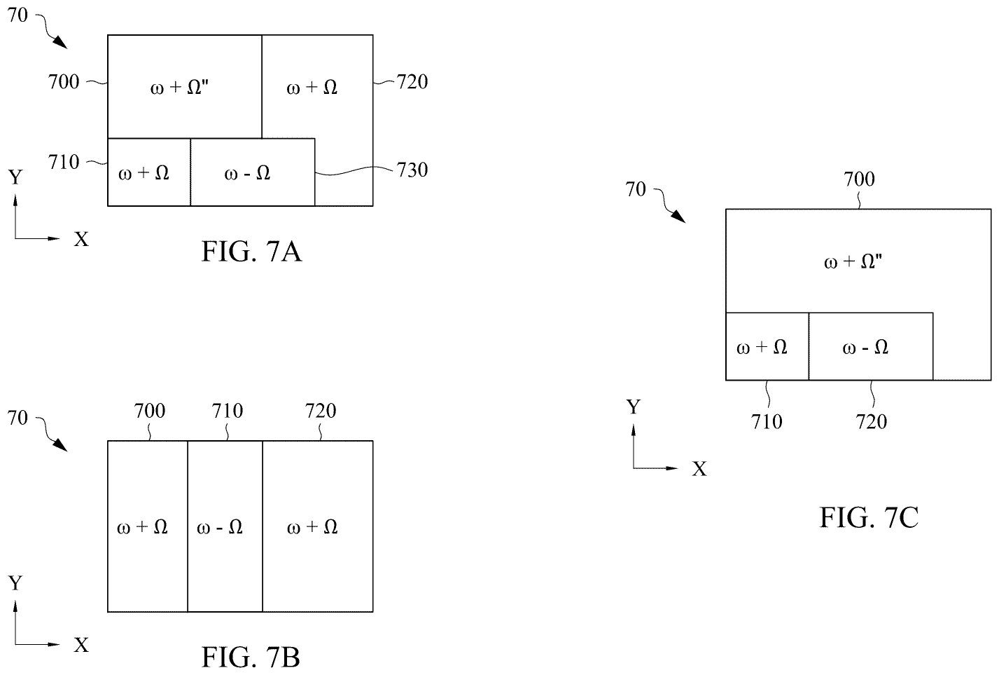

FIG. 5 is a flowchart of a method 50 of performing sensitivity verification in accordance with various embodiments. FIGS. 6A and 6B are views illustrating a defect sensitivity verification operation in accordance with various embodiments. FIG. 7 is a plan view of a substrate in accordance with various embodiments. The acts illustrated in FIG. 5 may be performed in accordance with the system 10 described with reference to FIGS. 1-4E and 6A-10. Method 50 is an example and is not intended to limit the present disclosure to what is explicitly illustrated in method 50. Additional acts can be provided before, during and after the method 50 and some acts described can be replaced, eliminated, or moved around for additional embodiments of the methods. For example, the method 50 may be used for inspecting a mask, a wafer or the like. Not all acts are described herein in detail for reasons of simplicity. Acts of method 70 are described below with reference to elements of the system 10 of FIGS. 1-4 and 6B-10. Many of the acts may be performed by a controller 1000 described with reference to FIG. 10. For example, the controller 1000 may execute instructions to perform the acts of method 50. It should be understood that the method 50 is not limited to being performed by the system 10 and/or the controller 1000 and may be performed by systems and/or controllers that differ in one or more respects from the system 10 and/or controller 1000 in other embodiments.

In FIG. 5, the method 50 begins with act 500, in which exposure tests are performed for two or more wavelengths of light. In the example of FIGS. 4A-4E, a first exposure test may be performed for the first light 462, a second exposure test may be performed for the second light 464 and a third exposure test may be performed for the third light 466. In some embodiments, each of the first, second and third exposure tests may include a number of operations, such as power and intensity measurement, wavelength measurement, focus and/or alignment measurement, optional pulse duration and/or timing measurement, aberration measurement, system checks, and the like.

Power and intensity measurement may include operating a power meter to measure initial output power of the selected light. A beam profiler may be operated to confirm that the laser beam has substantially uniform intensity across its profile. Wavelength calibration may include measuring wavelength via a wavelength meter or a spectrometer to measure operating wavelength of the laser. Focusing and alignment may include a coarse alignment in which the laser is aligned to an optical path, so that the beam passes through any lenses, beam expanders or other optical components along the optical path. A fine alignment may be performed to more precisely align the laser using micrometer stages or other fine-tuning mechanisms. Focus measurement may include operating a focal plane array or similar device to focus the laser beam at a target plane where a mask will be placed. Pulse duration and timing measurement can include measuring pulse duration via an autocorrelator or other time-domain measurement device to determine the laser pulse duration. Aberration measurement may include checking for aberrations via wavefront sensing equipment to identify any optical aberrations such as astigmatism or spherical aberrations.

FIG. 6A depicts an example of a wavelengths exposure test according to act 500 in accordance with various embodiments. The wavelengths exposure test may be performed via a calibration substrate 60, which may a calibration mask 60, a calibration wafer 60, or the like. FIG. 6A depicts a calibration mask 60 that includes four different material layers or multilayers 600, 610, 620, 630. The layer 600 can be a substrate in some embodiments. For example, the layer 600 may be or include glass, such as fused silica or ultra-low expansion (ULE) glass. The multilayer 610 may be a reflective multilayer stack that includes alternating layers of two or more different materials, such as silicon and molybdenum. The layer 620 may be an absorber layer that can absorb any light that is not reflected, and may include tantalum, boron nitride or the like. The layer 630 may be a capping layer, which can be a thin layer of material, such as ruthenium or silicon, that is deposited on top of the absorber layer to protect the calibration mask 60 from contamination and/or oxidation. Fewer or additional layers may be included in the calibration mask 60, such as an adhesion layer, buffer layer, anti-reflective coating (ARC) layer, etch stop layer, and the like.

One or more of the layers 600, 610, 620, 630 may have a surface that is exposed. Due to feature sizes of the layers 600, 610, 620, 630 being different from each other, each of the exposed surfaces may be illuminated via light of a different respective wavelength. For example, the layer 630 may be exposed to first light 662 having first wavelength ω−Ω, the layer 620 may be exposed to second light 664 having second wavelength ω+Ω, and the layer 600 may be exposed to third light 666 having third wavelength ω+Ω″. The third wavelength ω+Ω″ may exceed the second wavelength ω+Ω, which may exceed the first wavelength ω−Ω. During the exposure test, the lights 662, 664, 666 are directed at the calibration mask 60. Reflections of the lights 662, 664, 666 may be measured using one or more of the measurements described previously. For example, power and intensity, beam profile, wavelength, focus and alignment and the like may be measured based on the reflections of the lights 662, 664, 666.

Act 510 follows act 500 and includes measuring resolution of the mask inspection system. In some embodiments, the resolution is measured via a modulation transfer function (MTF) operation, a Fourier transform analysis, a combination thereof, or the like.

In the MTF, a test target may be provided, which may be a high-resolution test target with selected spatial frequencies. The test target can be an MTF target with sinusoidal or bar patterns, for example. The test target is imaged through an optical system, which may have an imaging setup that is similar in most respects to actual operational conditions. Images are acquired via a high-resolution detector, accounting for potential sources of noise or aberrations. Software may be operated to analyze the acquired images, such as measuring how well the system reproduces the various spatial frequencies in the test target. An MTF may be plotted as a curve depicting contrast (e.g., in percentage) as a function of spatial frequency. A point where the contrast drops below a selected threshold (e.g., 10%) may be taken as a resolution limit. Based on the MTF results, adjustments may optionally be made to the optical system to improve performance thereof.

In the Fourier transform analysis, a test pattern with selected, finely spaced features may be imaged. For nanometer-scale resolution, the test pattern may have features on the order of the selected resolution (e.g., a few nanometers). A high-quality image(s) of the test pattern may be captured via a high-resolution detector, which may include taking multiple shots and averaging the shots to improve signal-to-noise ratio. A 2D Fourier transform may be performed on the acquired image to convert it into the frequency domain, which can reveal spatial frequency components present in the image. The Fourier-transformed image may be inspected to identify highest spatial frequencies that are clearly represented, which may correspond to the finest details that the system can resolve. In some embodiments, an inverse Fourier transform can be applied to reconstruct an image using only the higher-order frequencies to validate the system's capability in resolving those frequencies. Based on the Fourier analysis, the system may be fine-tuned to achieve the selected resolution.

Act 520 follows act 510 and includes performing a surface quality sanity check or sanity test. The sanity check may be performed on the calibration substrate and may be or include one or more of a visual inspection, atomic force microscopy, scanning electron microscopy, reflectivity measurements, X-ray reflectometry, interferometry, and the like. The sanity check may be performed to determine whether obvious defects are present on the calibration substrate, such as scratches, dust or other particles. In some embodiments, the sanity check may determine whether reflectivity and/or flatness across the calibration substrate is substantially uniform. In response to the sanity check failing, the calibration substrate may be repaired, reworked or replaced. In response to the sanity check passing, the calibration substrate may be used in following acts 530 and 540.

Act 530 follows act 520 and includes performing optics calibration. The optics calibration can include calibrating one or more of focus, astigmatism, flare, shading, polarization, beam size, gain, and the like of the optical system including the laser light source, one or more lenses, AOM, and the like. The calibration can be based on measurement data generated in acts 500 and 510.

Act 540 follows act 530 and includes performing a defect sensitivity verification. An example of defect sensitivity verification is depicted in FIG. 6B. When performing defect sensitivity verification, particles 640 may be deposited on the calibration substrate that act as “defects” to be detected by the optical system. The particles 640 may be nanoscale particles. Deposition of the particles 640 may be by spraying or another suitable deposition method. The particles 640 may be deposited on exposed surface of the layers 600, 610, 620, 630. In FIG. 6B, the particles 640 are deposited on exposed surface of the layers 600, 620, 630.

Following deposition of the particles 640, verification may be performed to determine whether the particles 640 can be detected via the lights 662, 664, 666 that have been calibrated in act 530. Detection of the particles 640 may include determining count of the particles 640. In response to determining that the particles 640 can be detected properly, the method 50 can proceed to act 550. In response to determining that the particles 640 are not detected properly, acts 510, 520, 530 and 540 may be repeated to recalibrate the optical system and/or repair, rework or replace the calibration substrate.

Act 550 follows act 540. In response to the defect sensitivity verification passing, suitable parameters of the optical system can be taped out. For example, light source wavelength, AOM frequency, slit opening size, lens positioning/angles and the like that are associated with passing the defect sensitivity verification may be stored for subsequent use in a mask inspection operation.

FIGS. 7A-7C are diagrams depicting a substrate 70 in accordance with various embodiments. The substrate 70 may be a calibration mask, a calibration wafer, a production mask, a production wafer or the like.

As depicted in FIG. 7A, and in the method 50, the substrate 70 may include at least two different regions 700, 710, 720, 730 that may be exposed via light of two or more different wavelengths ω+Ω″, ω+Ω, ω−Ω. The substrate 70 depicted in FIG. 7A includes four regions 700, 710, 720, 730. The first region 700 is selected for exposure to first light of a first wavelength ω+Ω″. The second region 710 and the third region 720 are selected for exposure to a second light of a second wavelength ω+Ω that may be shorter than the first wavelength ω+Ω″. The fourth region 730 may be selected for exposure to a third light of a third wavelength ω−Ω, which is shorter than the second wavelength ω+Ω. For example, the first wavelength ω+Ω″ may be a second-order modulation of a base wavelength ω, whereas the second and third wavelengths ω+Ω, ω−Ω may be first-order modulations of the base wavelength ω.

In some embodiments, the substrate 70 is a production mask or production wafer. Namely, following inspection, the substrate 70 will be used directly in a semiconductor processing operation, either to reflect light carrying a pattern in photolithography as a production mask or to undergo processing (e.g., deposition, etching, annealing, epitaxial growth, and the like) that will result in an integrated circuit (IC) die. The system 10 described with reference to FIGS. 1-6B is operable to inspect different regions of the substrate 70 via light of different wavelengths. For example, the first and second regions 700, 710 may have different types of pattern design from each other, such as bars, stripes, lines, dots, polygons, or the like. In another example, the first and third regions 700, 720 may have different depths from each other, such as is described with reference to FIGS. 6A and 6B. In yet another example, the third and fourth regions 720, 730 may have different materials from each other, such as is described with reference to FIGS. 6A and 6B. As depicted in FIG. 7A, two or more of the regions may be inspected using the same wavelength of light, such as the second and third regions 710, 720.

Arrangement of the regions 700, 710, 720, 730 may correspond to different circuit functional regions, different material regions, different depths, or another appropriate method of arrangement. The regions 700, 710, 720, 730 may be of the same or different sizes from each other. The regions 700, 710, 720, 730 may be arranged in a regular pattern or may be arranged without a regular pattern, as depicted in FIG. 7A.

FIG. 7B depicts a substrate 70 that has three regions 700, 710, 720 that are to be exposed by light of two different wavelengths ω+Ω, ω−Ω. The three regions 700, 710, 720 are arranged along a first horizontal direction (e.g., an X-axis direction) and extend along a second horizontal direction (e.g., a Y-axis direction) that is transverse the first horizontal direction. The second region 710 is between the first and third regions 700, 720. The first, second and third regions 700, 710, 720 may have differences in types of pattern design, depth, material or the like, as described with reference to FIG. 7A.

FIG. 7C depicts a substrate 70 that has three regions 700, 710, 720 that are to be exposed by light of three different wavelengths ω+Ω″, ω+Ω, ω−Ω. As described with reference to FIGS. 7A and 7B, the three regions 700, 710, 720 may have differences in types of pattern design, depth, material or the like.

It should be understood that the substrate 70 can include fewer or additional regions that are to be exposed by light of fewer or additional wavelengths than those depicted in FIGS. 7A-7C. For example, the substrate 70 may include five or more regions that are to be exposed by light of five different wavelengths, such as a base/primary wavelength, two 1^{st}-order modulated wavelengths and two 2^{nd}-order modulated wavelengths. In some embodiments, more than five wavelengths may be used.

FIGS. 8A-9B are views of systems for inspecting a substrate in accordance with various embodiments. FIGS. 8A and 9A depict the systems during a calibration operation that precedes an inspection operation. FIGS. 8B and 9B depict the systems during the inspection operation.

In FIG. 8A, the system 80 includes a light source 800, a first lens 810, a beam steering assembly or system 820, a filter assembly 830, a spectrometer 840 and a stage 82. The system 80 may be operable to calibrate the light source 800 and the first lens 810 and to inspect a mask 84 (or other substrate) positioned on the stage 82.

The light source 800 may be a multiwavelength light source similar to the multiwavelength light sources described with reference to FIGS. 1-4E. The light source 800 may be operable to generate light beams of different wavelengths and select one of the light beams to be outputted as a light beam 85 to the first lens 810.

The first lens 810 may be an objective lens. The first lens 810 is operable to focus light 86 to a focal plane associated with the substrate 84 on the stage 82. In some embodiments, the first lens 810 includes a different type of lens instead of the objective lens. The focused light 86 can be generated by another focal assembly that can assist in inspection, for example, by one or more of a concave mirror, zone plate, reflective parabolic mirror, or the like.

The spectrometer 840 may be similar in most respects to the spectrometers

described with reference to FIGS. 1-4E. In the system 80, the spectrometer 840 is positioned below the stage 82. In operation, the stage 82 may be positioned outside of an optical path of the light 86 during a calibration or verification phase, such that the spectrometer 840 receives light 87. The spectrometer 840 may generate wavelength amplitude/intensity data 850 based on the light 87.

When incoming laser light 85 passes through the first lens 810, which may be an objective lens, the beam size thereof becomes larger beyond the focal plane, as depicted in FIG. 8A. The system 80 includes a beam steering assembly 820 that follows the first lens 810 and receives the light 86. The light 86 that has exited the first lens 810 has expanded beam size beyond the focal plane. The beam steering assembly 820 beneficially collects the light 86 and directs the light 86 as the light 87 toward the spectrometer 840. The light 87 exits the beam steering assembly 820. In some embodiments, the beam steering assembly 820 includes a second lens 822, which is followed by a mirror 824, which is followed by a third lens 826. The second lens 822 may be operable to collect the light 86. The mirror 824 is operable to bend the light 86, for example, by 90 degrees. The third lens 826 may further focus the light 86 as the light 87 onto a focal plane of a detector of the spectrometer 840. When calculating on target intensity (e.g., on a mask surface), a transmission rate of the lens(es) 810, 822, 826 and the filter assembly 830 and a reflectivity of the mirror 824 may be taken into account.

In some embodiments, intensity of the light 87 exiting the beam steering assembly 820 is high enough to destroy or damage the spectrometer 840. The system 80 includes a filter assembly 830 positioned following the beam steering assembly 820. The filter assembly 830 is positioned between the light 87 and the spectrometer 840, which is beneficial to reduce intensity of the light 87 prior to reaching the spectrometer 840. In some embodiments, the filter assembly 830 is or includes an optical attenuator, such as a fixed attenuator or a variable attenuator. The filter assembly 830 may include one or more neutral density filters, rotating neutral density filters, variable optical attenuators (VOAs), beam splitters, polarizers, apertures and/or pinholes, liquid crystal variable attenuators, combinations thereof, or the like. The filter assembly 830 may protect the detector of the spectrometer 840, which can be a delicate device that is easily damaged by exposure to too much light. The optical attenuator can be used to reduce the intensity of the incident light beam to a level that is safe for the detector. The filter assembly 830 can improve accuracy of measurements. In some embodiments, it is beneficial to reduce the intensity of the incident light beam to improve the accuracy of measurements made by the spectrometer 840. This is because the response of some detectors can be nonlinear, which can lead to errors in measurements if the intensity of the incident light beam is too high. The filter assembly 830 can increase dynamic range of measurements captured by the spectrometer 840. The dynamic range of a spectrometer is the range of light intensities that can be measured accurately. An optical attenuator can be used to extend the dynamic range of the spectrometer 840 by reducing the intensity of high-intensity light beams so that they can be measured accurately.

In FIG. 8A, operation of the light source 800, first lens 810, beam steering assembly 820 and filter assembly 830 may be calibrated and/or verified while the stage 82 is at a first position outside the path of the light 86.

In FIG. 8B, the stage 82 is in a second position in the path of the light 86. As such, information associated with the light 86 may be absent from wavelength amplitude/intensity data 852 generated by the spectrometer 840. The light 86 may be directed to various positions on the substrate 84 via motion of the stage 82 so as to perform inspection of the substrate 84. The substrate 84 may be similar in most respects to the substrate 70 described with reference to FIGS. 7A-7C. Namely, the system 80 may inspect a calibration mask, calibration wafer, production mask or production wafer. Inspection of the substrate 70 may be similar in most respects to that described with reference to FIGS. 1-7C. In some embodiments, one or more parameters of the light source 800 and the first lens 810 is adjusted in response to a result of inspecting the substrate 84 via the light 86.

During inspection of a production mask or production wafer, the system 80 may direct first light 86 of a first wavelength onto a first region of the substrate 84, then may direct second light 86 of a second wavelength different than the first wavelength onto a second region of the substrate 84. The first light 86 and the second light 86 may be selected via a wavelength selector as described with reference to FIGS. 1-4E. Additional light 86 of different wavelength(s) may be directed onto other regions of the substrate 84, again under selection by the wavelength selector. The system 80 may determine presence of one or more defects in the first, second and/or other regions of the substrate 84 based on sensing of the first, second and additional lights 86 via an imaging system, such as the CCD or CMOS imaging devices described with reference to FIG. 1.

FIGS. 9A and 9B depict a system 90 in accordance with various embodiments. The system 90 is similar in many respects to the system 80 described with reference to FIGS. 8A and 8B, and like reference numerals refer to like elements. In the system 90, a compact beam dump device 920 is included that is beneficial for installation into confined spaces. The beam dump device 920 collects a portion of the light 86, which is then reflected into a collector lens 926 to gather the light intensity and spectrum intensity via optical fiber 930 into the spectrometer 840. The beam dump device 920 prevents light 86 from returning via the optical path, which can destroy or damage optics or degrade an inspection result. Laser stability and power of the light source 800 can also be controlled through the system 90.

In FIG. 9A, the stage 82 is in the first position, such that the light 86 is incident on a low-reflectivity mirror 924 that partially overlaps the light 86 and reflects the portion 97 of the light 86 toward the collector lens 926. The portion 97 of the light 86 is directed into the optical fiber 930 via the collector lens 926. Because only a portion 97 of the light 86 is collected and that portion is reflected by the low-reflectivity mirror 924, intensity of the portion 97 of the light 86 that reaches the spectrometer 840 is low enough that the filter assembly 830 may be omitted in the system 90.

In FIG. 9B, the stage 82 is in the second position in which the substrate 84 is in the optical path of the light 86. As such, the light 86 is reflected and/or absorbed by the substrate 84 and is no longer partially transmitted to the spectrometer 840 via the mirror 924, lens 926 and optical fiber 930. The substrate 84 may be inspected via the light 86. In some embodiments, one or more parameters of the light source 800 and the first lens 810 is adjusted in response to a result of inspecting the substrate 84 via the light 86.

FIG. 10 is a schematic view of a controller 1000 in accordance with various embodiments. The controller 1000 may be an embodiment of the controller 180 described with reference to FIG. 1. The controller 1000 may perform operations described with reference to FIGS. 1-9B. The controller 1000 is described with reference to the system 10 and the method 50. The controller 1000 is also operable to perform operations of the systems 20, 30, 40, 80, 90.

In FIG. 10, the controller or control system 1000 includes a processor 1002, a memory 1100, a data interface 1010 and a network interface 1012. Some elements of the controller 1000 may be omitted from view for simplicity of illustration. For example, the controller 1000 may include a power supply (e.g., voltage regulator), analog-to-digital converters (ADCs), digital-to-analog converters (DACs), pulse width modulation (PWM) controller, clocks and timing circuitry, and the like.

The control system 1000 generates output control signals for controlling operation of one or more components of the system 10. The control system 1000 may receive input signals from one or more components of the system 10.

Control system 1000 includes a processor 1002 and a non-transitory, computer readable storage medium 1004 encoded with, i.e., storing, computer program code 1006, i.e., a set of executable instructions. Computer readable storage medium 1004 is also encoded with instructions 1007 for interfacing with components of system 10. The processor 1002 is electrically coupled to the computer readable storage medium 1004 via a bus 1008. The processor 1002 is also electrically coupled to an I/O interface 1010 by bus 1008. A network interface 1012 is also electrically connected to the processor 1002 via bus 1008. Network interface 1012 is connected to a network 1014, so that processor 1002 and computer readable storage medium 1004 are capable of connecting to external elements via network 1014. The processor 1002 is configured to execute the computer program code 1006 encoded in the computer readable storage medium 1004 in order to cause control system 1000 to be usable for performing a portion or all of the operations as described with respect to system 10.

In some embodiments, the processor 1002 is a central processing unit (CPU), a multi-processor, a distributed processing system, an application specific integrated circuit (ASIC), and/or a suitable processing unit.

In some embodiments, the computer readable storage medium 1004 is an electronic, magnetic, optical, electromagnetic, infrared, and/or a semiconductor system (or apparatus or device). For example, the computer readable storage medium 1004 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 1004 includes a compact disk-read only memory (CD-ROM), a compact disk-read/write (CD-R/W), and/or a digital video disc (DVD).

In some embodiments, the storage medium 1004 stores the computer program code 1006 configured to cause control system 1000 to perform the operations as described with respect to system 10 and method 50. In some embodiments, the storage medium 1004 also stores information needed for performing the operations as described with respect to system 10 and method 50, such as a set of executable instructions to perform the operations as described with respect to system 10 and method 50.

In some embodiments, the storage medium 1004 stores instructions 1007 for interfacing with system 10. The instructions 1007 enable processor 1002 to generate operating instructions readable by elements of the system 10 to effectively implement the operations as described with respect to system 10 and method 50.

Control system 1000 includes I/O interface 1010. I/O interface 1010 is coupled to external circuitry. In some embodiments, I/O interface 1010 includes a keyboard, keypad, mouse, trackball, trackpad, and/or cursor direction keys for communicating information and commands to processor 1002.

Control system 1000 also includes network interface 1012 coupled to the processor 1002. Network interface 1012 allows control system 1000 to communicate with network 1014, to which one or more other computer systems are connected. Network interface 1012 includes wireless network interfaces such as BLUETOOTH, WIFI, WIMAX, GPRS, or WCDMA; or wired network interface such as ETHERNET, USB, or IEEE-1394.

Control system 1000 may be configured to receive information related to the spectrometers 110, 140 and the imaging device calibration apparatus 150 through I/O interface 1010. The information is transferred to processor 1002 via bus 1008 and then stored in computer readable medium 1004 as parameters 1016. Control system 1000 can be configured to receive information related to a threshold value through I/O interface 1010. In some embodiments, the threshold value is received from an operator. The information is stored in computer readable medium 1004 as threshold value parameter 1018. For example, the threshold value parameter 1018 may be associated with the digital data outputted by the spectrometer 480 described with reference to FIGS. 4A-4C. In one example, an amplitude of light at a selected wavelength may be compared with the threshold value parameter 1018, and a determination may be made whether to adjust one or more parameters of the light source 400, the lenses 410, 450, the AOM 430, the wavelength selector 470, or the like. In another example, the defect sensitivity measured in act 540 of the method 50 may be compared with the threshold value parameter 1018, and based on a comparison result (e.g., the defect sensitivity exceeding the threshold value), the suitable parameters of the optical system may be selected in act 550.

During operation, in some embodiments, processor 1002 executes a set of instructions to determine whether the amplitude of light has exceeded or is below a threshold value. Based on the above determinations, processor 1002 generates a control signal to instruct one or more components of the system 10 to adjust a parameter thereof. In some embodiments, the control signal is transmitted using I/O interface 1010. In some embodiments, the control signal is transmitted using network interface 1012.

The parameter(s) adjusted via the control signal can include parameter(s) associated with the light source 200. For example, when the nonlinear light source 200 has a tunable wavelength, the wavelength may be modulated based on a type of the nonlinear light source 200.

Embodiments may provide advantages. Inclusion of a tunable or selectable light source having multiple wavelengths improves calibration and/or inspection performance for different regions of a substrate, such as a mask or wafer. The different regions may have different patterns, different depths, different materials, and the like. Each region may be exposed to light of a wavelength that is beneficial for detecting defects, which reduces missed defect signals and false defect detections.

In accordance with at least one embodiment, a method includes positioning a substrate in an optical path of a multiwavelength light source; generating a first detection result by exposing a first region of the substrate to a first light having a first wavelength band, the first light being selected by the multiwavelength light source; and generating a second detection result by exposing a second region of the substrate to a second light having a second wavelength band that does not overlap the first wavelength band, the second light being selected by the multiwavelength light source.

In accordance with at least one embodiment, a method includes generating a first detection result by exposing a first region of a substrate to a first light of a first wavelength; generating a second detection result by exposing a second region of the substrate to a second light of a second wavelength; generating at least one parameter of an optical system based on the first detection result and the second detection result; depositing a plurality of particles on the first and second regions; determining a defect sensitivity of an inspection system by exposing the plurality of particles to the first light and the second light; and in response to the defect sensitivity exceeding a threshold value, performing an inspection based on the at least one parameter of the optical system.

In accordance with at least one embodiment, a system includes a multiwavelength light source including a light source and a wavelength selector in an optical path of light generated by the light source. The system also includes a spectrometer operable to measure a spectrum of a first light selected by the wavelength selector; a mask stage operable to position a mask in the optical path; and a controller operable to adjust at least one parameter of the multiwavelength light source in response to the spectrum of the first light.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
positioning a substrate in an optical path of a multiwavelength light source;
generating a first detection result by exposing a first region of the substrate to a first light having a first wavelength, the first light being selected by the multiwavelength light source; and
generating a second detection result by exposing a second region of the substrate to a second light having a second wavelength different from the first wavelength, the second light being selected by the multiwavelength light source.

2. The method of claim 1, further comprising:
generating the first light and the second light by an acousto-optical modulator of the multiwavelength light source.

3. The method of claim 1, further comprising:
selecting the first light by a wavelength selector.

4. The method of claim 3, wherein the selecting includes positioning an opening of the wavelength selector in a path of the first light by an actuator.

5. The method of claim 4, wherein the selecting includes adjusting a size of the opening based on digital data generated by a spectrometer that receives the first light.

6. The method of claim 4, wherein the positioning includes moving the opening via a piezoelectric transducer.

7. The method of claim 1, wherein the first region and the second region have different material from each other.

8. A method comprising:
generating a first detection result by exposing a first region of a substrate to a first light of a first wavelength;
generating a second detection result by exposing a second region of the substrate to a second light of a second wavelength;
generating at least one parameter of an optical system based on the first detection result and the second detection result;
determining a defect sensitivity of an inspection system by exposing the first and second regions to the first light and the second light; and
in response to the defect sensitivity exceeding a threshold value, performing an inspection based on the at least one parameter of the optical system.

9. The method of claim 8, wherein the generating at least one parameter includes generating a radio frequency signal that drives an acousto-optical modulator of a light source that generates the first and second lights.

10. The method of claim 8, wherein the performing an inspection includes inspecting a mask.

11. The method of claim 8, further comprising spraying a plurality of nanoscale particles on the first and second regions.

12. The method of claim 8, further comprising:
generating the first light and the second light by a nonlinear light source, the first light being zeroth-order light and the second light being first-order light.

13. The method of claim 8, further comprising:
generating the first light by a first single-wavelength light source; and
generating the second light by a second single-wavelength light source different than the first single-wavelength light source.

14. The method of claim 8, further comprising:
prior to the generating a first detection result, detecting a spectrum of the first light by a spectrometer.

15. A system, comprising:
a multiwavelength light source including:
a light source; and
a wavelength selector in an optical path of light generated by the light source;
a first spectrometer positioned at an outlet of the multiwavelength light source and operable to measure a spectrum of first light output by the multiwavelength light source;
a substrate stage operable to position a mask in the optical path; and
a second spectrometer positioned below the substrate stage and operable to measure a spectrum of second light; and
a controller operable to adjust at least one parameter of the multiwavelength light source in response to the spectrum of at least one of the first light or the second light.

16. The system of claim 15, wherein the multiwavelength light source further comprises:
an acousto-optical modulator between the light source and the wavelength selector.

17. The system of claim 15, wherein the light source comprises a plurality of single-wavelength light sources.

18. The system of claim 15, wherein the wavelength selector includes an opening having an opening size.

19. The system of claim 18, wherein the wavelength selector includes a piezoelectric transducer operable to adjust position of the opening.

20. The system of claim 18, wherein the wavelength selector is operable to pass one light beam therethrough while blocking other light beams.
